(19) United States
(12) Patent Application Publication
(10) Pub. No.: US 2006/0244090 A1
(43) Pub. Date: Nov. 2, 2006

(54) Method for fabricating an integrated circuit comprising a photodiode and corresponding integrated circuit

(75) Inventors: Francois Roy, Seyssins (FR); Arnaud Tournier, Grenoble (FR); Yann Marcellier, Grenoble (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/400,728

(22) Filed: Apr. 7, 2006

(30) Foreign Application Priority Data
Apr. 11, 2005 (FR) 0503570

(51) Int. Cl. H01L 31/06

(52) U.S. Cl. 257/462; 438/309; 257/E31.053

(57) ABSTRACT

An integrated circuit includes a photodiode produced from the formation of a stack of three semiconductor layers. An overdoped storage zone is formed in a second (middle) layer of the stack. A read transistor connected to the photodiode includes a gate formed above the stack and source/drain regions formed in a third (upper) layer of the stack. A first (bottom) layer of the stack forms a floating substrate. During integrated circuit fabrication, an implantation mask is placed above the gate and the stack having an opening which exposes a part of the gate and a part of the upper surface of the stack lying beside the exposed part of the gate. An oblique implantation of dopants is then made through the opening in the mask to form the storage zone such that it is at least partially located underneath the gate area of the read transistor.

### PRIORITY CLAIM

The present application claims priority from French Application for Patent No. 05 03570 filed Apr. 11, 2005, the disclosure of which is hereby incorporated by reference.

### BACKGROUND OF THE INVENTION

1. Technical Field of the Invention

The present invention relates to microelectronics, in particular integrated circuits including photodiodes.

2. Description of Related Art

Image sensors based on semiconductor components exploit the principle of the conversion of photons into electron/hole pairs in silicon. More precisely, the charges created in the photosensitive zones are stored in the photodiode and are subsequently read using an electronic system. This electronic system, which controls the photodiode, includes in particular the read transistor which converts the charges stored in the photodiode into an electrical quantity.

Advantageously, but without implying limitation, the invention applies to CMOS image sensors, and more particularly to VMIS (“Vth Modulation Image Sensors”) which are image sensors based on modulation of the threshold voltage of an MOS transistor. In this regard, reference may be made to the article by Takashi Miida (T. Miida et al., “A 1.5 Mpixel Imager with Localized Hole-Modulation Method”, ISSCC Dig. Tech. Pap., pp. 42-43 February 2002) which is incorporated herein by reference.

This type of CMOS transistor consists of a buried photodiode and an MOS transistor which is slightly modified because its substrate is a floating substrate, i.e. its potential cannot be accessed via an electrode, for example. This floating substrate acts as a storage zone for charges during their integration, i.e. when the incident light generates electron-hole pairs in the photosensitive zones.

More precisely, the charges may be stored in a particular heavily doped zone lying under the gate, inside the floating substrate, this overdoped zone being referred to as a “pocket” according to a term commonly used by the person skilled in the art.

The parameters of this particular zone, for example its doping and its relative position with respect to the source and the gate, are fundamental given that this storage zone is the basis of all the operating modes of the pixel: integration, modulation and refresh. The performance of the device is consequently dictated in particular by the characteristics of this particular zone.

More particularly, its location vis-a-vis the source-side channel in the case of a so-called “source follower” layout is the catalyst of the signal amplification during the read phase.

Conventionally, the so-called “pocket” zone is implanted according to the masking technique. A mask is produced on the stack of semiconductor layers forming the photodiode, with the exception of an exposed zone, where the storage zone is produced by standard implantation. Once it has been produced, the gate and then source and drain regions are formed.

The masking technique, however, has the major drawback of poor control over the relative position of the storage zone with respect to the source and the drain. This is because the photolithography responsible for the opening of the mask before implantation and the photolithography responsible for etching the gate have numerous uncertainties. It is consequently impossible to set the relative position of the storage zone vis-à-vis the channel of the transistor, and therefore to control its location with respect to the source.

These technological uncertainties entail a problem with the reproducibility of critical parameters in the photodiode, from one pixel to another. More precisely, given that the exact location of the storage zone under the gate is not controlled, the performance may vary from one pixel to another.

For conventional production of the storage zone, it is furthermore formed at the start of the photodiode production process, which involves a high risk that dopant atoms will diffuse from the storage zone during the various anneals of the gate production phases. There is accordingly a need to provide a solution to this problem; and an embodiment of the invention relates to a different solution for producing the storage zone.

### SUMMARY OF THE INVENTION

A first aspect of the invention relates to a method for fabricating an integrated circuit comprising the production of a photodiode, including the formation of a stack of three semiconductor layers and the formation of an overdoped storage zone in the second layer of the stack, and the production of a read transistor including the formation of a gate above the stack.

According to a general characteristic of this first aspect of the invention, the formation of the storage zone comprises the production of an implantation mask above the gate and the stack, having an opening which exposes a part of the gate and a part of the upper surface of the stack lying beside the exposed part of the gate. Oblique first implantation of the dopant is then carried out through the opening.

In other words, the storage zone (pocket) is produced by carrying out oblique implantation after forming the gate of the read transistor. The implantation of the dopant atoms is then controlled according to an angle of attack, so as to deposit the dopants under the gate. The storage zone is thus self-aligned with respect to the gate, which makes it possible to have the same location of the storage zone at the same position under the gate from one pixel to another.

According to one embodiment, an electrode semiconductor zone, for example the source zone, is produced by vertical second implantation beside the part of the gate which has not been masked, the gate being used as a mask for the second implantation.

According to this embodiment, the storage zone is produced just before the electrode semiconductor zone, which makes it possible to limit the diffusion problems present in the prior art solutions.

The implantation angle of the dopants in order to produce the storage zone is preferably more than 25° with respect to the vertical, so that the storage zone comes in contact with the electrode semiconductor zone produced by the second implantation.

The implantation angle used when producing the storage zone is much greater than the implantation angles conventionally employed. This angle value makes it possible to produce a storage zone both lying under the gate and extending outside the gate, so that it can come in contact with the source zone. By producing the source zone as close as possible to the storage zone, the conversion factor of the photodiode is improved.

Another aspect of the invention relates to an integrated circuit comprising, in and on a semiconductor substrate, a read transistor and a photodiode having a semiconductor layer and a charge storage zone which are more heavily doped than the semiconductor layer.

According to a general characteristic of this other aspect of the invention, the storage zone extends partially under the gate and partially outside the gate.

An electrode semiconductor zone, for example the source zone, lying on the side of the gate where the storage zone extends, preferably comes in contact with the storage zone.

According to an implementation for an integrated circuit comprising a plurality of read transistors and photodiodes, each storage zone lies at the same position under the gate of each transistor.

The invention also relates to an image sensor comprising at least one pixel associated with an integrated circuit as defined above.

In accordance with an embodiment of the invention, a method for fabricating an integrated circuit comprises: forming a stack of three semiconductor layers relating to a photodiode; producing a read transistor for the photodiode including the formation of a gate above the stack; producing an implantation mask above the gate and the stack, having an opening which exposes a part of the upper surface of the stack lying beside the gate; and obliquely implanting dopants through the opening to form an overdoped storage zone in a second layer of the stack.

In accordance with another embodiment, an integrated circuit comprises a photodiode formed from a stack of three semiconductor layers and a gate formed above an upper layer in the stack of three semiconductor layers. Source/drain regions are formed in the upper layer in the stack of three semiconductor layers on opposite sides of the gate. An overdoped storage zone is formed in a middle layer of the stack of three semiconductor layers, the overdoped storage zone being located partially under the gate and partially under one of the source/drain regions.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 schematically illustrates an image sensor according to the invention, formed by a plurality of cells equipped with photodiodes according to the invention;

FIG. 2 represents an embodiment of an integrated circuit according to the invention;

FIGS. 3 to 7 schematically illustrate the main steps of an implementation of the fabrication method according to the invention.

### DETAILED DESCRIPTION OF THE PREFERRED EMBODIMENTS

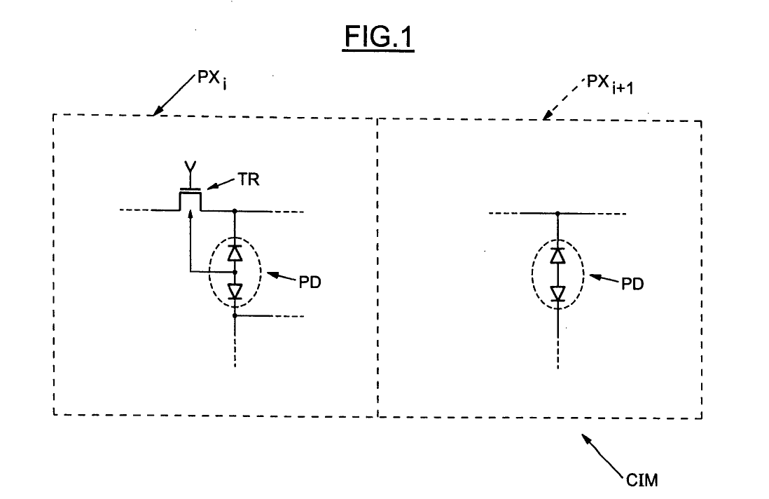

In FIG. 1, the reference CIM generally denotes an image sensor formed by a matrix of cells (or pixels) PXᵢ, including a photodiode PD as well as a read transistor TR, which is connected to the photodiode PD. Each cell PXᵢ may comprise complementary control means connected to the read transistors TR, for example a clear transistor, a selection transistor and a follower transistor.

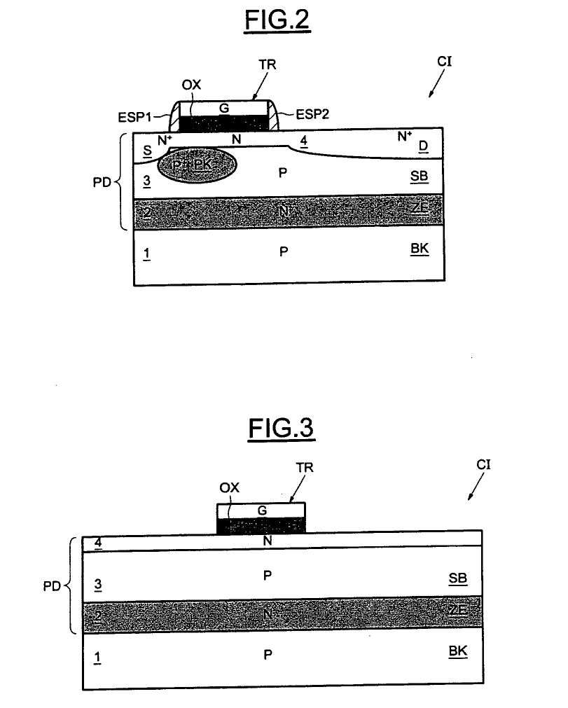

FIG. 2 illustrates the semiconductor structure of the photodiode PD of a cell PXᵢ in more detail.

The reference CI denotes an integrated circuit according to one embodiment of the invention, comprising the photodiode PD formed on a layer 1 of substrate BK (“bulk”), here p-doped and constituting the support of the integrated circuit. The integrated circuit CI also comprises the read transistor TR of a cell PXᵢ.

The photodiode PD comprises a stack of semiconductor layers formed above the support layer 1.

The layer BK is surmounted by another semiconductor layer 2, here n-doped, which forms a buried zone ZE, i.e. a barrier for the photo-generated charges.

The buried zone ZE is surmounted by a substrate layer 3, which in this case is a floating substrate SB, i.e. a closed zone whose potential cannot be modified or accessed with the aid of an electrode, for example.

The floating substrate SB comprises a p⁺-overdoped storage zone PK (“pocket”). This is because instead of storing the photo-generated charges in all of the substrate SB, they are stored in the localized storage zone PK. This makes the influence of each charge uniform, i.e. each charge can generate the same voltage value.

The integrated circuit CI comprises a last layer 4, here n-doped, so as to produce the photodiode PD.

This n-doped last layer 4 makes it possible to produce the source S and the drain D of the read transistor TR, both zones being n⁺-doped.

In the case of a CMOS image sensor, a read transistor is associated with a pixel of the sensor.

Above the stack of semiconductor layers, there is the gate G of the read transistor TR which is insulated from the stack of semiconductor layers by an oxide layer OX.

The read transistor TR furthermore comprises two spacers ESP1 and ESP2 on each side of the gate G.

The photodiode PD is therefore in this case formed by three layers defining two PN junctions (diodes), i.e. an upper junction formed by the n-doped layer 4 the p-doped layer 3 forming the substrate SB, and a lower junction formed by the layer 3 and the layer 2 of the buried zone ZE.

The last layer 1 forming the “bulk” substrate BK is used for support and a fixed and constant bias.

Reference will now be made more particularly to FIGS. 3 to 7, which describe the main steps of an implementation of the method according to the invention.

After having conventionally produced the stack of semiconductor layers 1 to 4, the gate G of the read transistor TR resting on the n-doped semiconductor layer 4 is produced (FIG. 3).

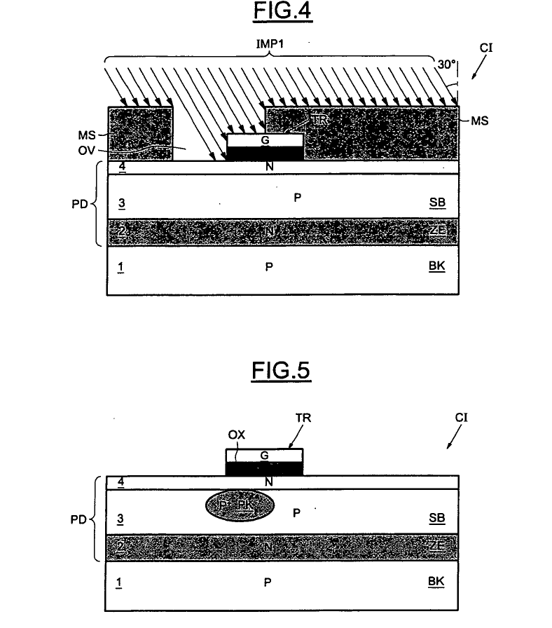

A resin layer is then deposited on the layer 4 and on the gate G (FIG. 4). An opening OV is subsequently defined by exposing and etching the resin. A resin mask MS has consequently been produced on the layer 4 and a part of the gate G. Only the opening OV due to etching the resin remains on the other part of the gate and the part of the layer 4 adjacent to the uncovered part of the gate, as represented in FIG. 4. The thickness of the resin mask MS is determined as a function of the intended implantation depth.

Once this mask MS has been produced, oblique first implantation IMP1 is carried out such that the implantation angle of the dopants makes an angle of more than 25° with the vertical, preferably 30°.

The person skilled in the art will know how to adapt the maximum value acceptable for the implantation angle as a function of the height of the resin mask, so that the implantation of the storage zone can take place under the gate.

By selecting such an angle, it will be possible to produce a storage zone PK lying both under the gate and extending outside the gate towards the uncovered part of the mask MS.

The implantation doses used for the implantation IMP1 are of the order of 1 to 2×10¹² at/cm².

The depth of the implantation IMP1 is preferably of the order of from 0.1 to 0.15 μm.

The dopants used may, for example, be boron or indium, which presents the advantage of having low diffusion. More generally, the doping method may use any electrically active dopant gas of the p-type in this case, or n-type in the case of a p-channel (or PMOS) transistor.

As can be seen in FIG. 5, after the implantation step IMP1, a storage zone PK is obtained lying under the gate as a function of the opening produced in the mask MS, and outside the gate, in this case of the same side as the zone where the source S of the transistor is produced.

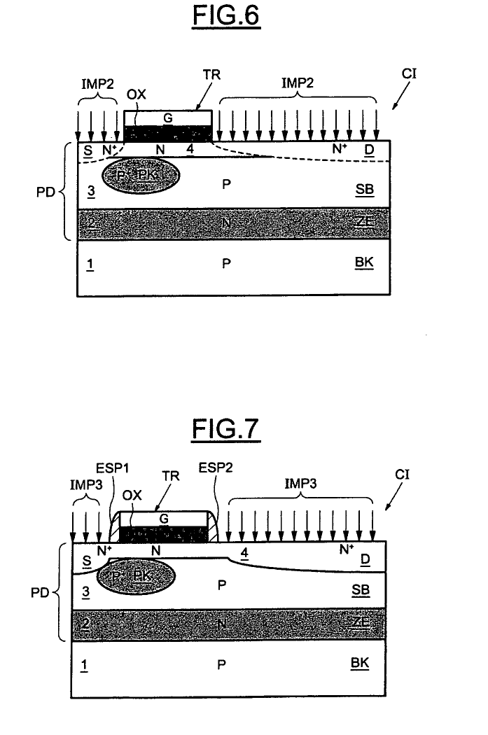

As can be seen in FIG. 6, second implantation IMP2 is subsequently carried out after having masked the gate G, so as to obtain the n⁺-doped source and drain zones S and D. As can be seen, the source zone S comes just in contact with the storage zone PK produced beforehand. If the IMP1 implantation angle had been less, the storage zone PK would then have been less spread and would have perturbed source zone S.

The spacers ESP1 and ESP2 of the transistor TR are then produced in a conventional way which is known per se (FIG. 7) above the layer 4 under the edges of the gate G. Third implantation IMP3 3 may then be carried out so as to dope the source and drain zones S and D more deeply.

Having produced the storage zone just before the formation of the source and drain zones limits the diffusion of dopants, which may perturb the bias of the source S, from the storage zone PK. This diffusion is in fact accentuated when the storage zone is produced before the gate, because it experiences the various anneals necessary for forming the gate.

The person skilled in the art will easily know how to adapt the method in the case of producing a storage zone which comes in contact with the drain of the transistor.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method for fabricating an integrated circuit, comprising:
forming a stack of three semiconductor layers relating to a photodiode;
producing a read transistor for the photodiode including the formation of a gate above the stack;
producing an implantation mask above the gate and the stack, having an opening which exposes a part of the gate and a part of the upper surface of the stack lying beside the exposed part of the gate; and
obliquely first implanting dopants through the opening to form an overdoped storage zone in a second layer of the stack.

2. The method according to claim 1, further comprising producing an electrode semiconductor zone for the read transistor by vertical second implantation beside the part of the gate which has not been masked, the gate being used as a mask for the second implantation.

3. The method according to claim 2, wherein obliquely first implanting comprises using an oblique first implantation angle of the dopants in order to produce the storage zone that is more than about 25° with respect to the vertical, so that the storage zone comes in contact with the electrode semiconductor zone produced by the second implantation.

4. The method according to claim 1, wherein obliquely first implanting comprises using an oblique first implantation angle of the dopants in order to produce the storage zone that is more than about 25° with respect to the vertical.

5. The method according to claim 1, wherein a lowest layer in the stack of three semiconductor layers is a floating substrate layer for the photodiode.

6. An integrated circuit, comprising:
a semiconductor substrate;
a read transistor; and
a photodiode having a semiconductor layer and a charge storage zone which are more heavily doped than the semiconductor layer, wherein the charge storage zone extends partially under the gate and partially outside the gate.

7. The integrated circuit according to claim 6, wherein an electrode semiconductor zone for the read transistor lying beside the gate where the charge storage zone extends comes in contact with the charge storage zone.

8. The integrated circuit according to claim 6, wherein the photodiode comprises a stack of three semiconductor layers including: a bottom layer which is a floating substrate; a middle layer within which the charge storage zone is formed, and an upper layer within which source/drain regions of the read transistor are formed.

9. An integrated circuit image sensor, comprising a plurality of pixels, wherein each pixel comprises a read transistor and a photodiode having a semiconductor layer and a charge storage zone which are more heavily doped than the semiconductor layer, wherein the charge storage zone extends partially under the gate and partially outside the gate.

10. The integrated circuit according to claim 9 wherein each charge storage zone lies at the same position under the gate of each read transistor across the plurality of pixels.

11. The integrated circuit according to claim 9, wherein the photodiode comprises a stack of three semiconductor layers including: a bottom layer which is a floating substrate; a middle layer within which the charge storage zone is formed, and an upper layer within which source/drain regions of the read transistor are formed.

12. A method for fabricating an integrated circuit, comprising:
forming a stack of three semiconductor layers relating to a photodiode;
producing a read transistor for the photodiode including the formation of a gate above the stack;
producing an implantation mask above the gate and the stack, having an opening which exposes a part of the upper surface of the stack lying beside the gate; and
obliquely implanting dopants through the opening to form an overdoped storage zone in a second layer of the stack.

13. The method of claim 12 wherein producing the read transistor comprises implanting dopants for a source/drain region in a third layer of the stack adjacent the gate.

14. The method of claim 13 wherein the source/drain region contacts the overdoped storage zone.

15. The method of claim 12 wherein obliquely implanting produces the overdoped storage zone in the second layer of the stack at least partially underlying the gate of the read transistor.

16. The method of claim 12, wherein obliquely implanting comprises using an oblique first implantation angle of more than about 25° with respect to normal from the upper surface of the stack.

17. The method according to claim 12, wherein a lowest layer in the stack of three semiconductor layers is a floating substrate layer for the photodiode.

18. An integrated circuit, comprising:
a photodiode formed from a stack of three semiconductor layers;
a gate formed above an upper layer in the stack of three semiconductor layers;
source/drain regions formed in the upper layer in the stack of three semiconductor layers on opposite sides of the gate; and
an overdoped storage zone formed in a middle layer of the stack of three semiconductor layers, the overdoped storage zone being located partially under the gate and partially under one of the source/drain regions.

19. The integrated circuit of claim 18 wherein a lower of the stack of three semiconductor layers is a floating substrate for the photodiode.

20. The integrated circuit of claim 18 wherein the one of the source/drain regions contacts the overdoped storage zone.
